(19) United States
(12) Patent Application Publication
(10) Pub. No.: US 2017/0359085 A1
(43) Pub. Date: Dec. 14, 2017

(54) CODING APPARATUS, TRANSPORT APPARATUS, AND CODING METHOD

(71) Applicants: FUJITSU LIMITED, Kawasaki-shi (JP); Mobile Techno Corp., Yokohama-shi (JP)

(72) Inventors: Taizo MAEDA, Kawasaki (JP); Yohei KOGANEl, Kawasaki (JP); Masanori YOFUNE, Yokohama (JP); Cong LI, Yokohama (JP)

(73) Assignees: FUJITSU LIMITED, Kawasaki-shi (JP); Mobile Techno Corp., Yokohama-shi (JP)

(21) Appl. No.: 15/606,893

(22) Filed: May 26, 2017

(30) Foreign Application Priority Data
Jun. 13, 2016 (JP) 2016-116861

(51) Int. Cl. H03M 13/11; H03M 13/00

(52) U.S. Cl. CPC H03M 13/1108; H03M 13/616

(57) ABSTRACT

A coding apparatus includes a check matrix, a calculator, a selector, and a synthesizer. The check matrix includes a parity operation matrix including a matrix along a diagonal, a circulant matrix positioned one row and a predetermined number of rows below the diagonal, and an information operation matrix. The calculator sets, in response to an input of a bit sequence of a message, every pattern of initial values to a less-significant bit sequence of parity bits corresponding to the number of the predetermined rows, and calculates parity bit sequences for the respective patterns of the initial values. The selector selects a parity bit sequence corresponding to one of the patterns of initial values when the less-significant bit sequence of the parity bit sequence matches the pattern of initial values. The synthesizer concatenates the selected parity bit sequence to the bit sequence of the message, and outputs the resultant code word.

### CROSS-REFERENCE TO RELATED APPLICATION

This application is based upon and claims the benefit of priority of the prior Japanese Patent Application No. 2016-116861, filed on Jun. 13, 2016, the entire contents of which are incorporated herein by reference.

### FIELD

The embodiments discussed herein are related to a coding apparatus, a transport apparatus, and a coding method.

### BACKGROUND

Recently having become available for digital coherent receivers used in optical transport systems is forward error correction (FEC) with soft-decision low-density parity check (LDPC), which exhibits a higher error-correction performance than hard-decision coding such as BCH coding or Reed-Solomon (RS) coding. FIG. 12 is a schematic for explaining exemplary bit-error-rate-to-signal-noise-ratio (BER-SNR) characteristics of error corrections using LDPC coding, and those using a hard-decision coding, in addition to LDPC coding. The BER-SNR characteristics illustrated in FIG. 12 exhibit waterfalls and an error floor. The error-correction performance can be improved when the waterfall is steep, and the error floor is brought to a lower position as much as possible. With the error correction with LDPC coding, however, it is difficult to achieve the transmission quality demanded in optical transport systems (BER of ≦1e⁻¹⁵), and the error floor occurs as indicated by the BER-SNR characteristics.

By combining the LDPC coding with a hard-decision coding, the error floor can be suppressed, while achieving the transmission quality of the optical transport systems BER—1e⁻¹⁵, as illustrated in FIG. 12. However, because FEC is required in the hard-decision coding, as well as in LDPC, the circuit size and power consumption are increased.

FIG. 13 is a schematic for explaining an exemplary parity check matrix for LDPC codes, and in which each column has a column weight of two or less. It is known that, in a parity check matrix, the position of the error floor will be higher when the column weight is two or less, as illustrated in FIG. 13. Therefore, by designing the parity check matrix so as not to include any column with a column weight of two or less, the error floor can be suppressed, and a steep gradient of the waterfall can be achieved.

Known as a coding algorithm for enabling the coding apparatus to be designed and to be implemented easily, and having a high error-correction performance are repeat-accumulate (RA) coding. FIG. 14 is a schematic for explaining an exemplary parity check matrix H20 for RA coding. The parity check matrix H20 illustrated in FIG. 14 is a matrix for designating an operational expression for calculating a parity bit sequence. The parity check matrix H20 includes an information operation matrix H21 that is used for an operational expression for assigning elements to predetermined bits of a message bit sequence, and a parity operation matrix H22 that is used for an operational expression for assigning elements to predetermined bits of a parity bit sequence. The information operation matrix H21 has an almost random structure, and is a matrix of three columns, including columns D1 to D3, by sixth rows, for example. The parity operation matrix H22 is a matrix of six columns, P1 to P6, by six rows, and having a structure in which the elements “1” are regularly arranged in the matrix along the diagonal and in the matrix positioned one row below the diagonal. Because the parity operation matrix H22 for RA coding, however, has columns with a column weight of two or less, the error floor will be higher. Available as a way to suppress the error floor by providing the parity operation matrix H22 with columns with a column weight of three or more is weight-3 repeat accumulate (w3RA) coding. FIG. 15 is a schematic for explaining an exemplary parity check matrix H30 for w3RA coding. The parity check matrix H30 for w3RA coding, illustrated in FIG. 15, includes an information operation matrix H31 and a parity operation matrix H32. The parity operation matrix H32 is a lower triangular matrix in which the elements “1” are regularly arranged not only in the matrix along the diagonal and the matrix positioned one row below the diagonal, but also in the matrix positioned three rows below the matrix along the diagonal.

FIG. 16 is a schematic for explaining an example of an operation of coding a message using the parity check matrix H30 illustrated in FIG. 15. It is assumed that a message u consists of [u1, u2, u3], and is [101], for example. A code word c is [u1, u2, u3, p1, p2, p3, p4, p5, p6] that is a concatenation of data [u1, u2, u3] and a parity bit sequence [p1, p2, p3, p4, p5, p6]. Each parity bit in the parity bit sequence is calculated sequentially using an operation of 0(mod2) on each column of the parity check matrix H30.

The first row in the parity check matrix H30 represents, focusing on the element “1”, an operational expression of the operation 0(mod2) of D1+D2+P1=0. The operational expression then calculates 1+0+P1=0 as P1=1 by assigning u1=1 and u2=0 to calculate p1=1, as a parity bit p1 corresponding to Pl. The second row of the parity check matrix H30 represents, focusing on the elements “1”, an operational expression of the operation 0(mod2) of D1+D3+P1+P2=0. The operational expression then calculates 1+1+1+P2=0 as P2=1 by assigning u1=1, u3=1, and P1=1, to calculate p2=1 as a parity bit p2 corresponding to P2.

The third row of the parity check matrix H30 represents, focusing on the elements “1”, an operational expression of the operation 0(mod2) of D3+P2+P3=0. The operational expression then calculates 1+1+P3=0 as P3=0 by assigning u3=1 and P2=1, to calculate p3=0 as a parity bit p3 corresponding to P3. The fourth row of the parity check matrix H30 represents, focusing on the elements “1”, an operational expression of the operation 0(mod2) of D2+P1+P3+P4=0. The operational expression then calculates 0+1+0+P4=0 as P4=1 by assigning u2=0, P1=1, and P3=0, to calculate p4=1 as a parity bit p4 corresponding to P4.

The fifth row of the parity check matrix H30 represents, focusing on the elements “1”, represents an operational expression of the operation 0(mod2) of D1+P2+P4+P5=0. The operational expression then calculates 1+1+1+P5=0 as P5=1 by assigning u1=1, P2=1, and P4=1, to calculate p5=1 as a parity bit p5 corresponding to P5. The sixth row of the parity check matrix H30 represents, focusing on the elements “1”, an operational expression of the operation 0(mod2) of D2+D3+P3+P5+P6=0. The operational expression then calculates 0+1+0+1+P6=0 as P6=0 by assigning u2=0, u3=1, P3=0, and P5=1, to calculate p6=0 as a parity bit p6 corresponding to P6.

As a result, the parity bit sequence will be [p1, p2, p3, p4, p5, p6]=[110110]. The coding apparatus can therefore output code word c [101110110] as a concatenation of the data [u1, u2, u3]=[101] and the parity bit sequence [110110]. Related art examples are disclosed in Japanese National Publication of International Patent Application No. 2008-541496 and International Publication Pamphlet No. WO 2006/120844.

Even with the use of w3RA coding, however, the error floor cannot be improved, because the columns P4, P5, and P6 in the parity operation matrix H32, which is included in the parity check matrix H30 illustrated in FIG. 16, all have column weights of two or less.

### SUMMARY

According to an aspect of an embodiment, a coding apparatus includes a parity check matrix, a calculator, a selector and a synthesizer. The parity check matrix includes a parity operation matrix including a matrix along a diagonal, a circulant matrix positioned one row below the diagonal, and a circulant matrix positioned a predetermined number of rows below the diagonal, and an information operation matrix. The calculator sets, in response to an input of a bit sequence of a message, every pattern of initial values to a less-significant bit sequence of parity bits corresponding to the number of the predetermined rows, the parity bits being used in calculating a parity bit sequence using an operational expression designated by the parity operation matrix and the information operation matrix, and calculates parity bit sequences for the respective patterns of the initial values. The selector selects a parity bit sequence corresponding to one of the patterns of initial values when the less-significant bit sequence of the parity bit sequence corresponding to such a pattern of initial values matches the pattern of initial values. The synthesizer concatenates the selected parity bit sequence to the bit sequence of the message, and outputs a resultant code word.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic for explaining an exemplary optical transport apparatus according to a first embodiment;

FIG. 2 is a schematic for explaining an exemplary parity check matrix for w3RA coding in the first embodiment;

FIG. 3 is a schematic for explaining an example of a coding unit;

FIG. 4 is a schematic for explaining an example of an accumulator unit according to the first embodiment;

FIG. 5 is a schematic for explaining an example of a processing operation performed by the coding unit in relation to a first coding process;

FIG. 6 is a schematic for explaining an example of an accumulator unit according to a second embodiment;

FIG. 7 is a schematic for explaining an example of a processing operation performed by the coding unit in relation to a second coding process;

FIG. 8 is a schematic for explaining an example of an accumulator unit according to a third embodiment;

FIG. 9 is a schematic for explaining an example of a processing operation performed by the coding unit in relation to a third coding process;

FIG. 10 is a schematic for explaining an exemplary parity check matrix for spatially-coupled RA coding in a fourth embodiment;

FIG. 11A is a schematic for explaining an example of BER-SNR characteristics of error corrections for spatially-coupled RA coding without the use of the present invention (without circulation);

FIG. 11B is a schematic for explaining an example of BER-SNR characteristics of error correction for spatially-coupled RA coding according to the fourth embodiment (with circulation);

FIG. 12 is a schematic for explaining an example of BER-SNR characteristics of error correction using LDPC coding and a combination of LDPC coding and a hard-decision algorithm;

FIG. 13 is a schematic for explaining an exemplary parity check matrix having column weights of two or less for LDPC coding;

FIG. 14 is a schematic for explaining an exemplary parity check matrix for RA coding;

FIG. 15 is a schematic for explaining an exemplary parity check matrix for w3RA coding; and

FIG. 16 is a schematic for explaining an example of the way in which a code word is generated using a parity check matrix in the coding unit.

### DESCRIPTION OF EMBODIMENTS

Preferred embodiments of the present invention will be explained with reference to accompanying drawings. The embodiments below, however, are not intended to limit the scope of the technology disclosed herein in any way. The embodiments below may also be combined as appropriate.

### [a] First Embodiment

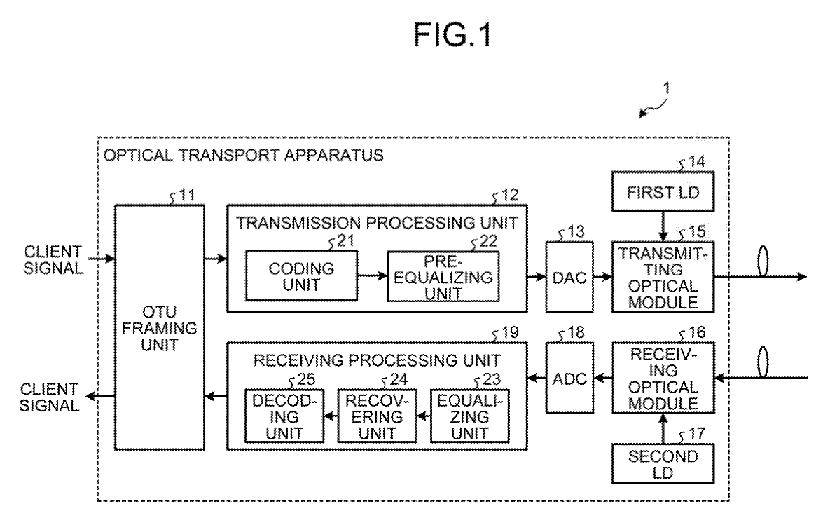

FIG. 1 is a schematic for explaining an exemplary optical transport apparatus 1 according to the first embodiment. The optical transport apparatus 1 includes an optical-channel transport unit (OTU) framing unit 11, a transmission processing unit 12, a digital-to-analog converter (DAC) 13, a first laser diode (LD) 14, and a transmitting optical module 15. The optical transport apparatus 1 also includes a receiving optical module 16, a second LD 17, an analog-to-digital converter (ADC) 18, and a receiving processing unit 19.

The OTU framing unit 11 is a processing unit that converts a client signal into an OTU frame, and that extracts a client signal from the OTU frame, for example. The transmission processing unit 12 includes a coding unit 21 and a pre-equalizing unit 22. The coding unit 21 is a coding apparatus that encodes the OTU frame received from the OTU framing unit 11, and outputs the code word c. The pre-equalizing unit 22 is a processing unit that executes various types of signal processing such as wavelength dispersion compensation, frequency offset compensation, and compensation of input/output characteristic of the optical module. The DAC 13 is a processing unit that converts the OTU frame into an analog signal. The transmitting optical module 15 is a processing unit that optically transmits the OTU frame having been converted into an analog signal, as an optical signal output from the first LD 14.

The receiving optical module 16 is a processing unit that receives the OTU frame from the second LD 17, as an optical signal. The ADC 18 is a processing unit that converts the OTU frame into a digital signal. The receiving processing unit 19 includes an equalizing unit 23, a recovering unit 24, and a decoding unit 25. The equalizing unit 23 is a processing unit that executes various types of signal processing such as wavelength dispersion compensation, frequency offset compensation, polarization mode dispersion compensation, and waveform distortion compensation. The recovering unit 24 is a processing unit that recovers a carrier phase. The decoding unit 25 is a processing unit that decodes the coded data. The decoding unit 25 corrects errors by decoding the code word repeatedly using the parity check matrix.

The coding unit 21 encodes the data using the parity check matrix H for w3RA coding, and outputs the code word c. The coding unit 21 encodes the data by performing an operation on the data using the parity check matrix H for w3RA coding. The code word c is a bit sequence [u1, u2, u3, p1, p2, p3, p4, p5, p6] having 9 bits in total that is a concatenation of an information bit sequence [u1, u2, u3] having 3 bits, and a parity bit sequence [p1, p2, p3, p4, p5, p6] having 6 bits.

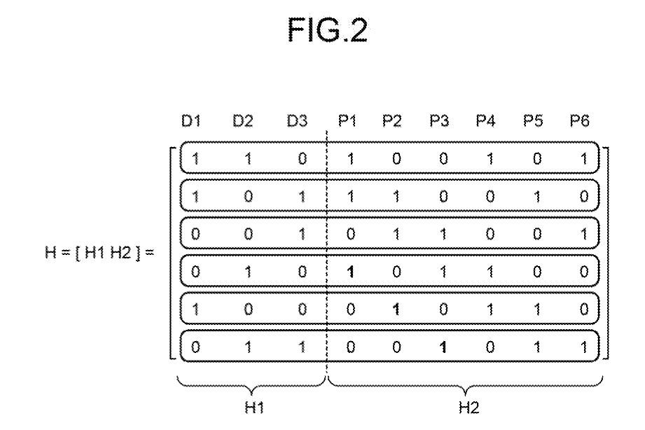

FIG. 2 is a schematic for explaining an example of the parity check matrix H for w3RA coding. The parity check matrix H illustrated in FIG. 2 is a matrix for designating an operational expression for calculating the parity bit sequence, and includes an information operation matrix H1 and a parity operation matrix H2. The information operation matrix H1 is a matrix of three columns, including columns D1, D2, and D3, by sixth rows. The information operation matrix H1 is a matrix used for an operation expression for assigning elements to predetermined bits of a message bit sequence, for example. The parity operation matrix H2 is a matrix of six columns, including P1 to P6, by sixth rows. The parity operation matrix H2 is a matrix used for an operation expression for assigning elements to predetermined bits of a parity bit sequence, for example.

The parity operation matrix H2 has a structure in which the elements “1” are regularly arranged in a matrix along the diagonal, in a circulant matrix positioned one row below the diagonal, and in a circulant matrix positioned a predetermined number of rows below the diagonal, e.g., a circulant matrix positioned three rows below the diagonal. In the circulant matrix positioned one row below the diagonal, the elements “1” are arranged in the second row in the column P1, in the third row in the column P2, in the fourth row in the column P3, in the fifth row in the column P4, in the sixth row in the column P5, and in the first row in the column P6. In the circulant matrix positioned three rows below the diagonal, the elements “1” are arranged in the fourth row in the column P1, in the fifth row in the column P2, in the sixth row in the column P3, in the first row in the column P4, in the second row in the column P5, and in the third row in the column P6. As a result, every column from P1 to P6 in the parity operation matrix H2 has a column weight of three or more. Therefore, the error floor can be reduced.

The first row of the parity check matrix H represents an operational expression of the operation 0(mod2) of D1+D2+P1+P4+P6=0. The second row of the parity check matrix H represents an operational expression of the operation 0(mod2) of D1+D3+P1+P2+P5=0. The third row of the parity check matrix H represents an operational expression of the operation 0(mod2) of D3+P2+P3+P6=0. The fourth row of the parity check matrix H represents an operational expression of the operation 0(mod2) of D2+P1+P3+P4=0. The fifth row of the parity check matrix H represents an operational expression of the operation 0(mod2) of D1+P2+P4+P5=0, and the sixth column of the parity check matrix H represents an operational expression of the operation 0(mod2) of D2+D3+P3+P5+P6=0. The parity bit sequence [p1, p2, p3, p4, p5, p6] is calculated using the operational expressions represented by the respective rows of the parity check matrix H.

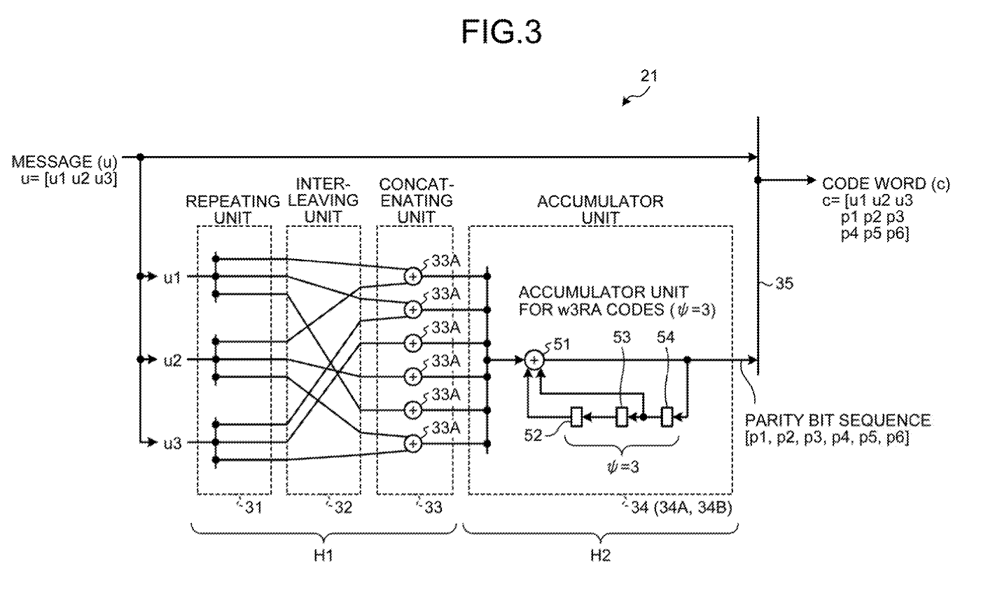

FIG. 3 is a schematic for explaining an example of the coding unit 21 according to the first embodiment. The coding unit 21 illustrated in FIG. 3 includes a repeating unit 31, an interleaving unit 32, a concatenating unit 33, an accumulator unit 34, and a synthesizing unit 35. The repeating unit 31 duplicates the message bits based on the column weight of the information operation matrix H1 in the parity check matrix H. The repeating unit 31 duplicates the three-bit bit sequence [u1, u2, u3] because the column weight of the information operation matrix H1 illustrated in FIG. 2 is “3”.

The interleaving unit 32 re-arranges the bit order of the bit sequence based on how “1” is arranged in each row of the information operation matrix H1. For example, with the first row [D1, D2, D3] specified as [110] having “1” in [D1, D2], the interleaving unit 32 acquires [10] from the message [101]. The concatenating unit 33 has six exclusive-OR (EXOR) 33A, for example, adding the bits based on the weight specified in the corresponding row of the information operation matrix H1. With the first row [D1, D2, D3] specified as [110], the concatenating unit 33 acquires D1+D2. The repeating unit 31, the interleaving unit 32, and the concatenating unit 33 make up the information operation matrix H1, and the weight (1) of H1 corresponds to the circuit wiring, as illustrated in FIG. 3. For example, with the first row with [D1, D2, D3] specified as [110], the first row of the concatenating unit 33 takes XOR of u1 and u2.

The accumulator unit 34 calculates the parity bit sequence [p1, p2, p3, p4, p5, p6] based on the structure of the parity operation matrix H2. The accumulator unit 34 is an accumulator unit for w3RA coding, for example, and includes an EXOR 51, a first shift register 52, a second shift register 53, and a third shift register 54 to be described later. The synthesizing unit 35 concatenates the bit sequence [u1, u2, u3] of the message and the parity bit sequence [p1, p2, p3, p4, p5, p6], and outputs the code word [u1, u2, u3, p1, p2, p3, p4, p5, p6].

While the first row of the parity check matrix H is an operational expression D1+D2+P1+P4+P5=0 in which the elements can be assigned to D1 and D2 as D1=1 and D2=0, P1, P4, and P5 are unknown. Therefore, the parity bit sequence [p4, p5, p6] from P4, P5, and P6 corresponding to the predetermined number of rows ψ=3 takes eight patterns of a set of initial values, including the first to the eighth. The first set of initial values is [000], the second set of initial values is [001], and the third set of initial values is [010]. The fourth set of initial values is [011], the fifth set of initial values is [100], and the sixth set of initial values is [101]. The seventh set of initial values is [110], and the eighth set of initial values is [111]. There is only one correct pattern for [p4, p5, p6] among all of these patterns. Because the circulant matrix is positioned the predetermined number of rows below, that is, positioned three rows below, in the parity operation matrix H2, the predetermined number of rows is three.

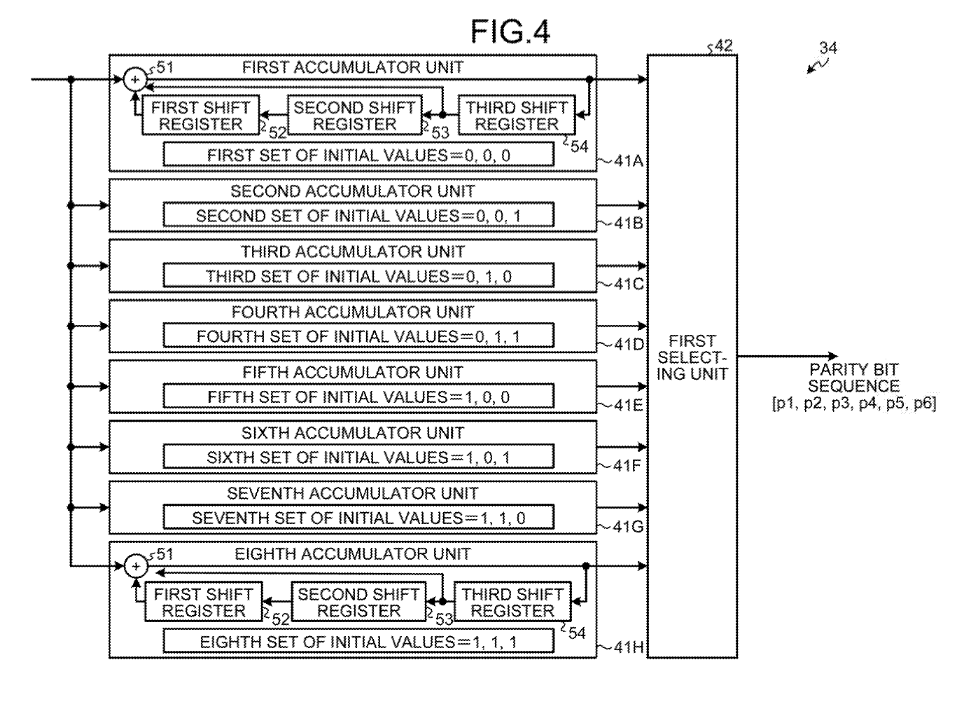

FIG. 4 is a schematic for explaining an example of an accumulator unit 34 according to the first embodiment. Internalized in the accumulator unit 34 illustrated in FIG. 4 are 2̂(predetermined number of rows)=2̂3=8 accumulator units. The accumulator unit 34 includes a first accumulator unit 41A, a second accumulator unit 41B, a third accumulator unit 41C, a fourth accumulator unit 41D, and a fifth accumulator unit 41E. The accumulator unit 34 also includes a sixth accumulator unit 41F, a seventh accumulator unit 41G, an eighth accumulator unit 41H, and a first selecting unit 42.

The first accumulator unit 41A includes an EXOR 51, a first shift register 52, a second shift register 53, and a third shift register 54. Each of the second to eighth accumulator units 41B to 41H also includes an EXOR 51, a first shift register 52, a second shift register 53 and a third shift register 54, in the same manner as the first accumulator unit 41A.

The first accumulator unit 41A sets the first set of initial values [000] to [p4, p5, p6], and calculates the parity bit sequence [p1, p2, p3, p4, p5, p6] based on the setting result. The second accumulator unit 41B sets the second set of initial values [001] to [p4, p5, p6], and calculates the parity bit sequence [p1, p2, p3, p4, p5, p6] based on the setting result. The third accumulator unit 41C sets the third set of initial values [010] to [p4, p5, p6], and calculates the parity bit sequence [p1, p2, p3, p4, p5, p6] based on the setting result.

The fourth accumulator unit 41D sets the fourth set of initial values [011] to [p4, p5, p6], and calculates the parity bit sequence [p1, p2, p3, p4, p5, p6] based on the setting result. The fifth accumulator unit 41E sets the fifth set of initial values [100] to [p4, p5, p6], and calculates the parity bit sequence [p1, p2, p3, p4, p5, p6] based on the setting result. The sixth accumulator unit 41F sets the sixth set of initial values [101] to [p4, p5, p6], and calculates the parity bit sequence [p1, p2, p3, p4, p5, p6] based on the setting result. The seventh accumulator unit 41G sets the seventh set of initial values [110] to [p4, p5, p6], and calculates the parity bit sequence [p1, p2, p3, p4, p5, p6] based on the setting result. The eighth accumulator unit 41H sets the eighth set of initial values [111] to [p4, p5, p6], and calculates the parity bit sequence [p1, p2, p3, p4, p5, p6] based on the setting result.

The first selecting unit 42 collects the parity bit sequences from the first to eighth accumulator units 41A to 41H, respectively, and determines whether the less-significant bit sequence [p4, p5, p6] of each of the parity bit sequence matches the set bit sequence. The less-significant bit sequence is a bit sequence corresponding to the predetermined number of rows ψ. For the parity bit sequence corresponding to the first accumulator unit 41A, the first selecting unit 42 determines the less-significant bit sequence [p4, p5, p6] of the parity bit sequence matches the first set of initial values [000]. For the parity bit sequence corresponding to the second accumulator unit 41B, the first selecting unit 42 determines whether the less-significant bit sequence [p4, p5, p6] of the parity bit sequence matches the second set of initial values [001]. For the parity bit sequence corresponding to the third accumulator unit 41C, the first selecting unit 42 determines whether the less-significant bit sequence [p4, p5, p6] of the parity bit sequence matches the third set of initial values [010]. For the parity bit sequence corresponding to the fourth accumulator unit 41D, the first selecting unit 42 determines whether the less-significant bit sequence [p4, p5, p6] of the parity bit sequence matches the fourth set of initial values [011]. For the parity bit sequence corresponding to the fifth accumulator unit 41E, the first selecting unit 42 determines whether the less-significant bit sequence [p4, p5, p6] of the parity bit sequence matches the fifth set of initial values [100]. For the parity bit sequence corresponding to the sixth accumulator unit 41F, the first selecting unit 42 determines whether the less-significant bit sequence [p4, p5, p6] of the parity bit sequence matches the sixth set of initial values [101]. For the parity bit sequence corresponding to the seventh accumulator unit 41G, the first selecting unit 42 determines whether the less-significant bit sequence [p4, p5, p6] of the parity bit sequence matches the seventh set of initial values [110]. For the parity bit sequence corresponding to the eighth accumulator unit 41H, the first selecting unit 42 determines whether the less-significant bit sequence [p4, p5, p6] of the parity bit sequence matches the eighth set of initial values [111].

If the less-significant bit sequence [p4, p5, p6] of the parity bit sequence matches the corresponding set of initial values in the setting, the first selecting unit 42 determines the parity bit sequence as being correct, and outputs the parity bit sequence having been determined as being correct to the synthesizing unit 35 as an output from the accumulator unit 34. The synthesizing unit 35 concatenates the bit sequence [u1, u2, u3] of the message and the parity bit sequence [p1, p2, p3, p4, p5, p6], and outputs the code word [u1, u2, u3, p1, p2, p3, p4, p5, p6].

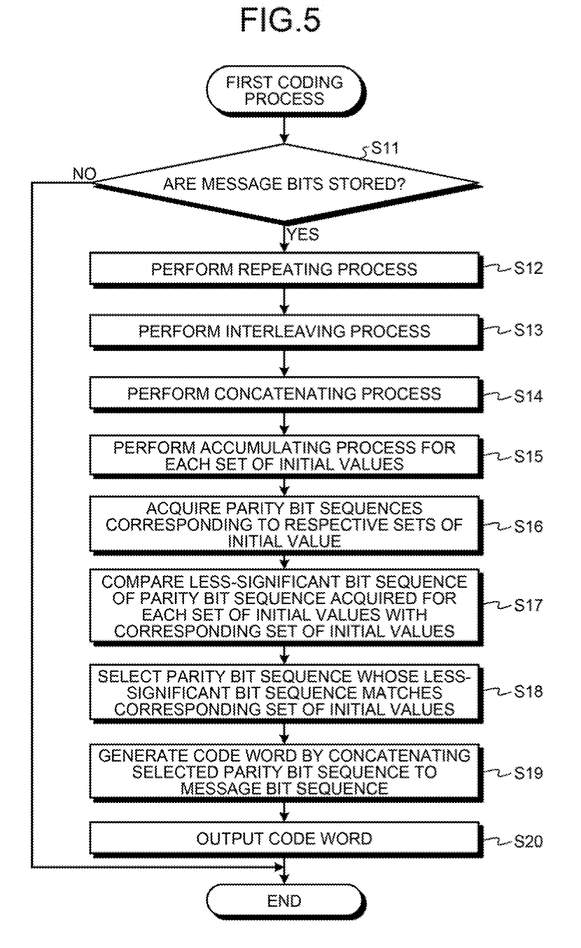

An operation of the optical transport apparatus 1 according to the first embodiment will now be explained. FIG. 5 is a flowchart for explaining an example of the processing operation performed by the coding unit 21 in relation to a first coding process. In FIG. 5, the coding unit 21 determines whether the bit sequence [u1, u2, u3] of the message has been stored (Step S11). If the bit sequence [u1, u2, u3] of the message has been stored (Yes at Step S11), the coding unit 21 executes the repeating process performed by the repeating unit 31 (Step S12).

After executing the repeating process, the coding unit 21 performs the interleaving process in the interleaving unit 32 (Step S13). The coding unit 21 then performs the concatenating process in the concatenating unit 33 (Step S14). The coding unit 21 then performs the accumulating processes for the respective sets of initial values in parallel, in the first accumulator unit 41A to the eighth accumulator unit 41H, respectively (Step S15). The coding unit 21 then outputs the parity bit sequences corresponding to the respective sets of initial values, from the accumulating processes performed by the first accumulator unit 41A to the eighth accumulator unit 41H, respectively (Step S16).

The coding unit 21 then compares the less-significant bit sequence [p4, p5, p6] of the parity bit sequence acquired for each set of initial values with the corresponding set of initial values in the setting (Step S17), and selects the parity bit sequence whose less-significant bit sequence matches the corresponding set of initial values in the setting (Step S18). The coding unit 21 then generates a code word c by concatenating the selected parity bit sequence to the message bit sequence (Step S19), and outputs the generated code word c (Step S20), and the processing operation illustrated in FIG. 5 is ended.

In the coding unit 21 according to the first embodiment, because the parity operation matrix H2 included in the parity check matrix H has a matrix along the diagonal, a circulant matrix positioned one row below the diagonal, and a circulant matrix a predetermined number of rows below the diagonal, e.g., three rows below from the diagonal, and each column of the parity check matrix H has a column weight of three or more, the coding unit 21 can improve the error floor.

Based on the information operation matrix H1 and the parity operation matrix H2 included in the parity check matrix H, and on the sets of initial values assigned to [p4, p5, p6], the coding unit 21 calculates a parity bit sequence corresponding to each set of the initial values, and compares the less-significant bit sequence of the parity bit sequence with the corresponding set of the initial values in the setting. The coding unit 21 then selects the parity bit sequence having the less-significant bit sequence matching the set of initial values, concatenates the parity bit sequence to the message bit sequence, and outputs the code word c. As a result, the parity bit sequence can be calculated even when used is a parity check matrix H in which each column has a column weight of three or more.

Moreover, in the coding unit 21, the first to the eighth accumulator units 41A to 41H corresponding to the respective sets of initial values are arranged in parallel, and are caused to calculate the parity bit sequences corresponding to all of the respective patterns of [p4, p5, p6]. Furthermore, the coding unit 21 compares the less-significant bit sequence of the parity bit sequence with the corresponding set of initial values in the setting, and selects the parity bit sequence with the less-significant bit sequence matching the corresponding set of initial values in the setting. As a result, the parity bit sequence can be calculated even when a parity check matrix H in which each column has a column weight of three or more is used.

In the first embodiment, the advantages achieved by RA coding can be achieved in the optical transport systems requiring high transmission quality. Moreover, because the additional use of a hard-decision-based error correction circuit is not required, an optical transport system with a circuit size and power consumption reduced can be implemented. In other words, receiving BER≦1e⁻¹⁵ can be achieved without the hard-decision circuit.

Explained as an example of the accumulator unit 34 according to the first embodiment is a configuration in which the first to the eighth accumulators 41A to 41H, to which respective sets of initial values corresponding to every pattern of the less-significant bit sequence [p4, p5, p6] of the parity bit sequence are set, are arranged in parallel. The embodiment is, however, not limited to such a configuration, and the accumulator unit 34 may include one accumulator unit. Such an embodiment will now be explained as a second embodiment. The elements that are the same as those in the optical transport apparatus 1 according to the first embodiment will be assigned with the same reference numerals, and the redundant explanations of such elements and the operations thereof will be omitted herein.

### [b] Second Embodiment

An accumulator unit according to the second embodiment is different from that according to the first embodiment in being provided with one tenth accumulator unit 43 in which the set of initial values set to the tenth accumulator unit 43 is sequentially updated, instead of providing the first to the eighth accumulator unit 41A to 41H in parallel, and the tenth accumulator unit 43 sequentially outputs the parity bit sequences corresponding to the respective patterns.

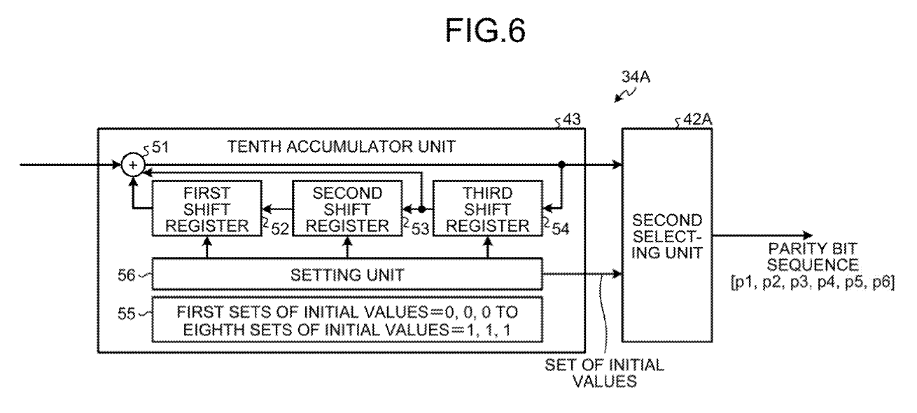

FIG. 6 is a schematic for explaining an example of an accumulator unit 34A according to the second embodiment. The accumulator unit 34A illustrated in FIG. 6 includes the tenth accumulator unit 43 and a second selecting unit 42A. The tenth accumulator unit 43 includes the EXOR 51, the first shift register 52, the second shift register 53, the third shift register 54, a pattern memory 55, and a setting unit 56. The pattern memory 55 is an area for storing therein every pattern of the initial values for [p4, p5, p6]. The setting unit 56 sets the initial values stored in the pattern memory 55 to the first to the third shift registers 52 to 54. There are eight patterns of the initial values including the first [000], the second [001], the third [010], the fourth [011], the fifth [100], the sixth “101”, the seventh [110], and the eighth [111], for example.

The setting unit 56 then sequentially outputs a parity bit sequence corresponding to each set of initial values, by reading the set of initial values from the pattern memory 55, and updating the first to the third shift registers 52 to 54 with the read initial values. In other words, the tenth accumulator unit 43 sequentially outputs the parity bit sequences corresponding to the respective sets of initial values, in response to the initial value updates performed by the setting unit 56.

The second selecting unit 42A receives inputs of the parity bit sequences corresponding to the respective sets of initial values, sequentially from the tenth accumulator unit 43, and compares the less-significant bit sequence [p4, p5, p6] of each of the received parity bit sequences with the corresponding set of initial values in the setting. If the less-significant bit sequence matches the corresponding set of initial values in the setting, the second selecting unit 42A outputs the parity bit sequence. If the less-significant bit sequence does not match the corresponding set of initial values in the setting, the second selecting unit 42A discards the parity bit sequence. The setting unit 56 keeps setting a set of initial values sequentially, until the second selecting unit 42A finds a match between the less-significant bit sequence and the corresponding set of initial values in the setting.

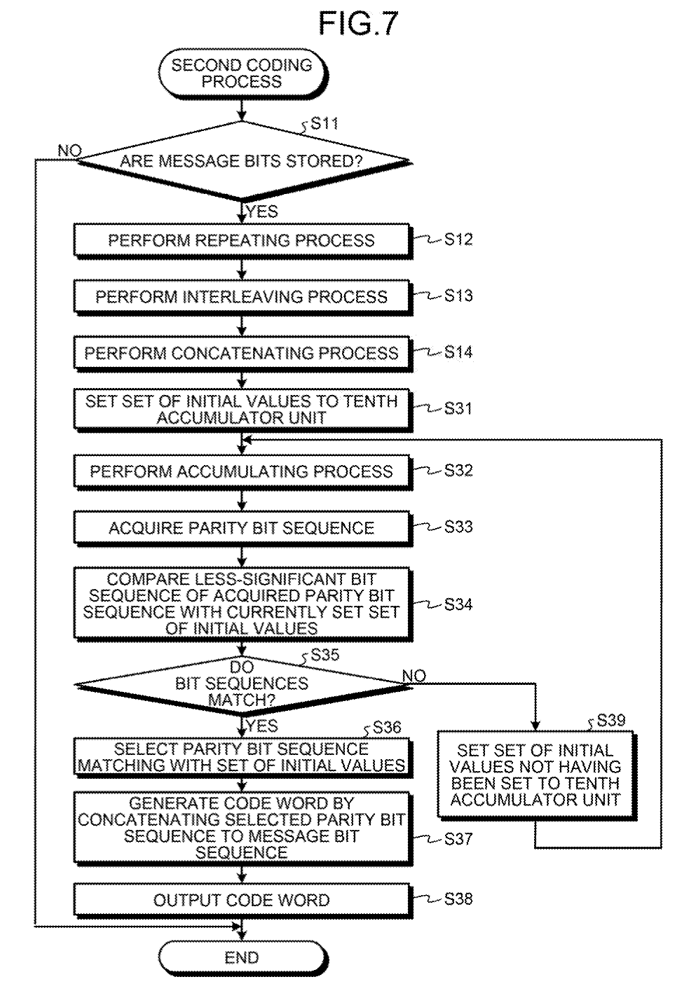

An operation of the optical transport apparatus 1 according to the second embodiment will now be explained. FIG. 7 is a flowchart for explaining an example of the processing operation performed by the coding unit 21 in relation to a second coding process according to the second embodiment. In FIG. 7, after performing the concatenating process at Step S14, the coding unit 21 sets a set of initial values to the tenth accumulator unit 43 (Step S31). The coding unit 21 then performs the accumulating process based on the set of initial values set to the tenth accumulator unit 43 (Step S32).

The coding unit 21 acquires the parity bit sequence for the corresponding set of initial values from the accumulating process (Step S33). The coding unit 21 compares the less-significant bit sequence of the set parity bit sequence with the current set of initial values in the setting (Step S34), and determines whether the less-significant bit sequence matches the current set of initial values in the setting (Step S35). If the less-significant bit sequence matches the current set of initial values (Yes at Step S35), the coding unit 21 selects the matching parity bit sequence (Step S36).

The coding unit 21 generates a code word c by concatenating the selected parity bit sequence to the message bit sequence (Step S37), and outputs the generated code word c (Step S38), and the processing operation illustrated in FIG. 7 is ended. If the less-significant bit sequence does not match the corresponding set of initial values (No at Step S35), the coding unit 21 sets another set of initial values not having been set yet to the tenth accumulator unit 43 (Step S39), and shifts the process to Step S32 to perform the accumulating process.

The coding unit 21 according to the second embodiment sequentially calculates the parity bit sequences corresponding to the respective sets of initial values by sequentially setting each of the sets of the initial values to the one tenth accumulator unit 43, and compares the less-significant bit sequence of each of the calculated parity bit sequences with the corresponding set of the initial values in the setting. If the less-significant bit sequence matches the corresponding set of initial values in the setting, the coding unit 21 outputs the parity bit sequence. The coding unit 21 then concatenates the parity bit sequence to the message bit sequence, and outputs the code word c. As a result, the parity bit sequence can be calculated even when a parity check matrix H in which each column has a column weight of three or more is used.

The embodiment is not limited to the configurations of the accumulator unit 34 (34A) according to the first and the second embodiments, and the accumulator unit using both of the parallel processing and the updating process may also be used. Such a configuration will now be explained as a third embodiment. The elements that are the same as those in the optical transport apparatus 1 according to the first embodiment will be assigned with the same reference numerals, and the redundant explanations of such elements and the operations thereof will be omitted herein.

### [c] Third Embodiment

An accumulator unit 34B according to the third embodiment is different from the accumulator unit 34 according to the first embodiment in being provided with four accumulator units including eleventh to fourteenth accumulator units 44A to 44D, and each of the eleventh to the fourteenth accumulator units 44A to 44D is enabled to be set with two sets of initial values.

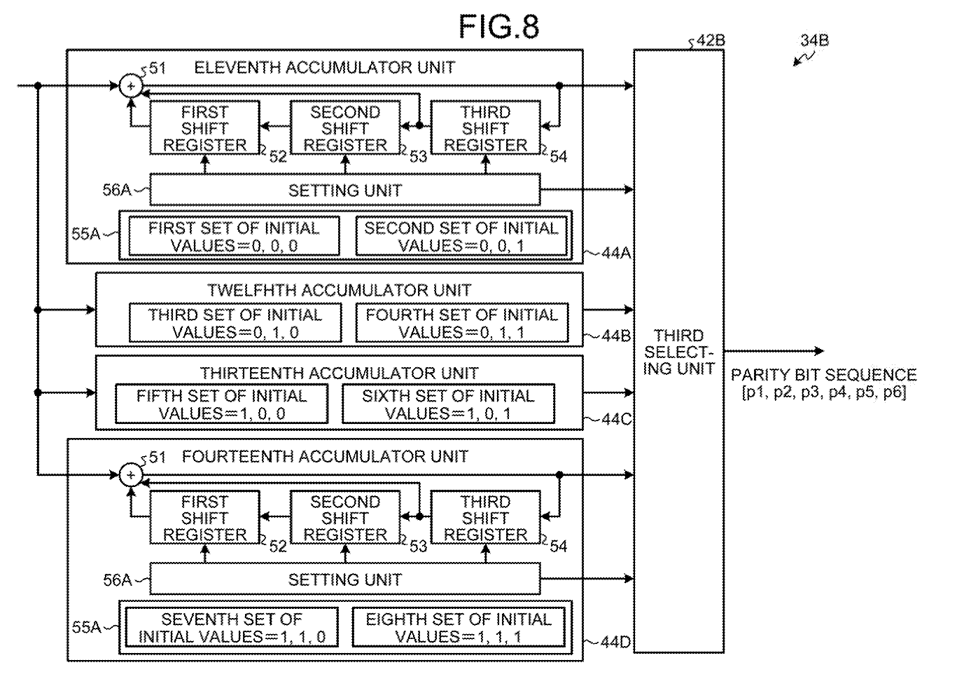

FIG. 8 is a schematic for explaining an example of the accumulator unit 34B according to the third embodiment. The accumulator unit 34B illustrated in FIG. 8 includes the eleventh accumulator unit 44A, the twelfth accumulator unit 44B, the thirteenth accumulator unit 44C, the fourteenth accumulator unit 44D, and a third selecting unit 42B.

Each of the eleventh to the fourteenth accumulator units 44A to 44D includes the EXOR 51, the first to the third shift register units 52 to 54, a pattern memory 55A, and a setting unit 56A.

The first set of initial values [000] and the second set of initial values [001] are stored in the pattern memory 55A in the eleventh accumulator unit 44A, as the two sets of initial values. The setting unit 56A in the eleventh accumulator unit 44A is enabled to set the first set of initial values [000] and the second set of initial values [001].

The third set of initial values [010] and the fourth set of initial values [011] are stored in the pattern memory 55A in the twelfth accumulator unit 44B, as the two sets of initial values. The setting unit 56A in the twelfth accumulator unit 44B is enabled to set the third set of initial values [010] and the fourth set of initial values [011].

The fifth set of initial values [100] and the sixth set of initial values [101] are stored in the pattern memory 55A in the thirteenth accumulator unit 44C as the two sets of initial values. The setting unit 56A in the thirteenth accumulator unit 44C is enabled to set the fifth set of initial values [100] and the sixth set of initial values [101].

The seventh set of initial values [110] and eighth set of initial values [111] are stored in the pattern memory 55A in the fourteenth accumulator unit 44D, as the two sets of initial values. The setting unit 56A in the fourteenth accumulator unit 44D is enabled to set the seventh set of initial values [110] and the eighth set of initial values [111].

The third selecting unit 42B receives inputs of parity bit sequences corresponding to the respective sets of initial values from the eleventh to the fourteenth accumulator unit 44A to 44D. The third selecting unit 42B then compares the less-significant bit sequence of each of the parity bit sequences with the corresponding set of initial values in the setting, and determines whether the less-significant bit sequence matches the corresponding set of initial values in the setting. If the less-significant bit sequence of the parity bit sequence matches the corresponding set of initial values in the setting, the third selecting unit 42B selects and outputs the parity bit sequence. If the less-significant bit sequence of the parity bit sequence does not match the corresponding set of initial values, the third selecting unit 42B discards the parity bit sequence.

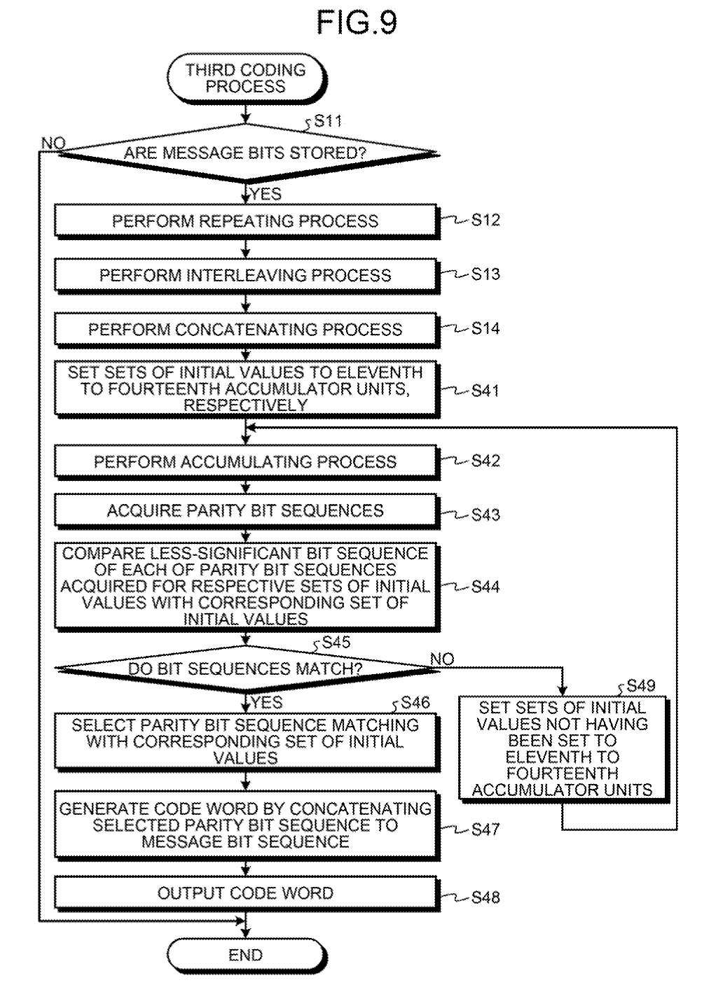

An operation of the optical transport apparatus 1 according to the third embodiment will now be explained. FIG. 9 is a flowchart for explaining an example of the processing operation performed by the coding unit 21 in relation to a third coding process according to the third embodiment. In FIG. 9, after performing the concatenating process at Step S14, the coding unit 21 sets respective sets of initial values to the eleventh to the fourteenth accumulator units 44A to 44D (Step S41). The coding unit 21 then performs the accumulating process based on the sets of initial values set to the eleventh to the fourteenth accumulator unit 44A to 44D (Step S42).

The coding unit 21 acquires the parity bit sequences for the respective sets of initial values from the accumulating process (Step S43). The coding unit 21 compares the less-significant bit sequence of each of the set parity bit sequences with the current set of initial values in the setting (Step S44), and determines whether the less-significant bit sequence matches the current set of initial values in the setting (Step S45). If the less-significant bit sequence matches the corresponding set of initial values in the setting (Yes at Step S45), the coding unit 21 selects the parity bit sequence corresponding to the matching set of initial values (Step S46).

The coding unit 21 generates a code word c by concatenating the selected parity bit sequence to the message bit sequence (Step S47), and outputs the generated code word (Step S48), and the processing operation illustrated in FIG. 9 is ended. If the less-significant bit sequence does not match the corresponding set of initial values in the setting (No at Step S45), the coding unit 21 sets the sets of initial values not having been set yet to the eleventh to the fourteenth accumulator units 44A to 44D, respectively (Step S49) to perform the accumulating process, and shifts the process to Step S42.

The coding unit 21 according to the third embodiment sequentially calculates the parity bit sequences corresponding to the respective sets of initial values by sequentially setting the sets of the initial values to the eleventh to the fourteenth accumulator units 44A to 44D, and compares the less-significant bit sequence of each of the calculated parity bit sequences with the corresponding set of the initial values in the setting. If the less-significant bit sequence matches the corresponding set of initial values in the setting, the coding unit 21 output the parity bit sequence. The coding unit 21 also concatenates the parity bit sequence to the message bit sequence, and outputs the code word c. As a result, the parity bit sequence can be calculated even when used is a parity check matrix H in which each column has a column weight of three or more.

Used as an example in the first to the third embodiments described above is w3RA coding, but the embodiment is not limited to w3RA coding, and the embodiment can also be used for spatially-coupled RA coding. Such an embodiment will now be explained as a fourth embodiment. The elements that are the same as those in the first embodiment will be assigned with the same reference numerals, and the redundant explanations of such elements and the operations thereof will be omitted herein.

### [d] Fourth Embodiment

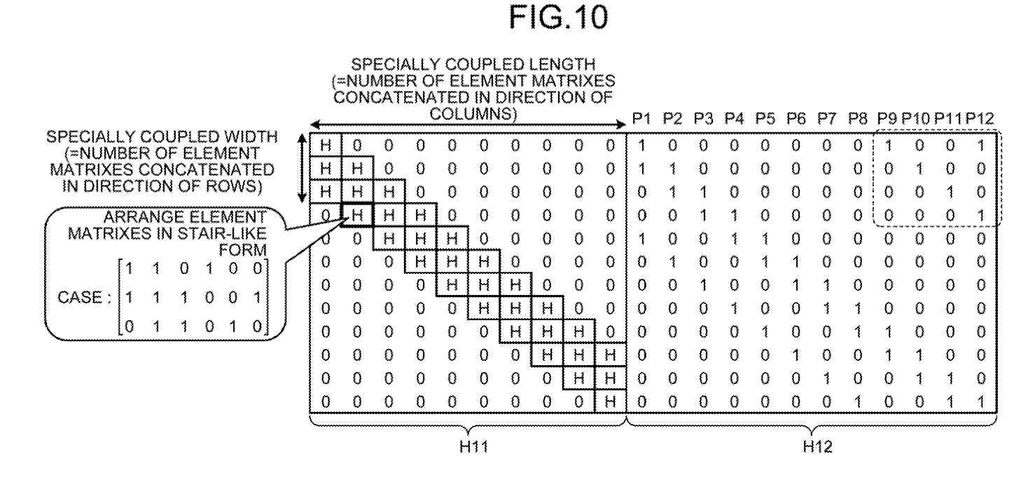

Spatially coupled RA coding is implemented as spatially coupled LDPC using the information operation matrix H11 for RA coding or w3RA coding, and element matrixes each of which is rendered as a space, are concatenated. FIG. 10 is a schematic for explaining an exemplary parity check matrix H10 for spatially-coupled RA coding.

The parity check matrix H10 illustrated in FIG. 10 includes an information operation matrix H11 and a parity operation matrix H12. The parity operation matrix H12 has a structure in which the elements “1” are regularly arranged in a matrix along the diagonal, in a circulant matrix positioned one row below the diagonal, and in a circulant matrix along a predetermined number of rows below the diagonal, e.g., the fourth row below the diagonal. In such a case, the bit sequences to be set in the predetermined rows of the parity operation matrix H12, that is, the bit sequences representing the entire respective sixteen patterns of four-digit less-significant bit sequence [p9, p10, p11, p12] are set to sixteen accumulator units. There are 2̂(predetermined number of rows)=2̂4=16 patterns of initial values. The sixteen accumulator units are arranged in parallel. As a result, the sixteen accumulator units are output sixteen different parity bit sequences corresponding to the respective set bit sequences.

The first selecting unit 42 then determines whether the less-significant bit sequence of the parity bit sequence [p9, p10, p11, p12] matches the corresponding set of initial values in the setting, and output the parity bit sequence with the less-significant bit sequence matching the corresponding set of initial values in the setting to the synthesizing unit 35.

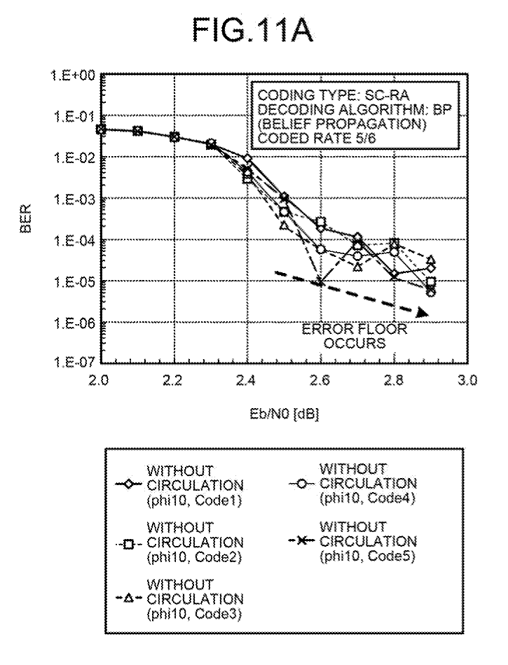

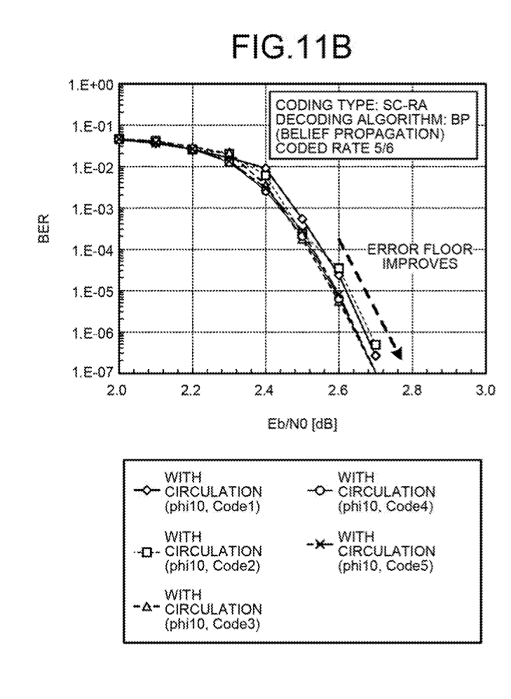

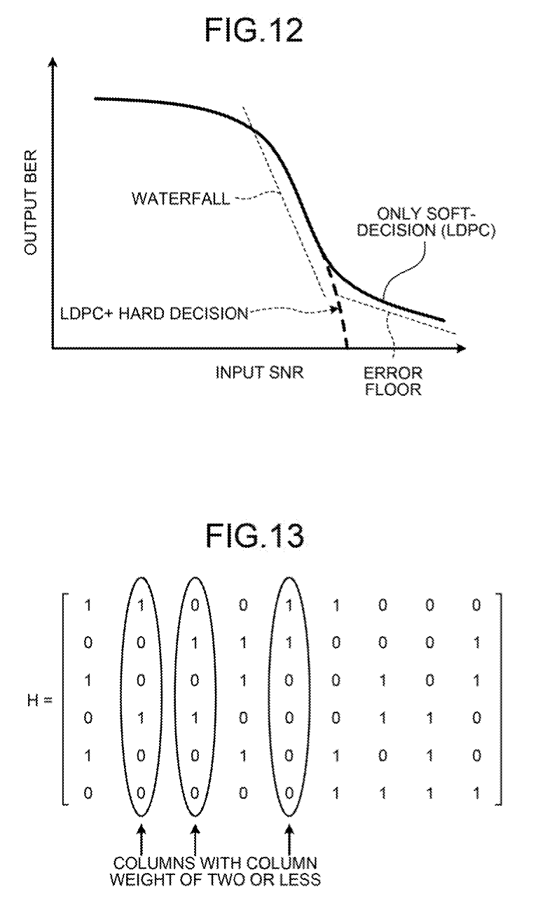

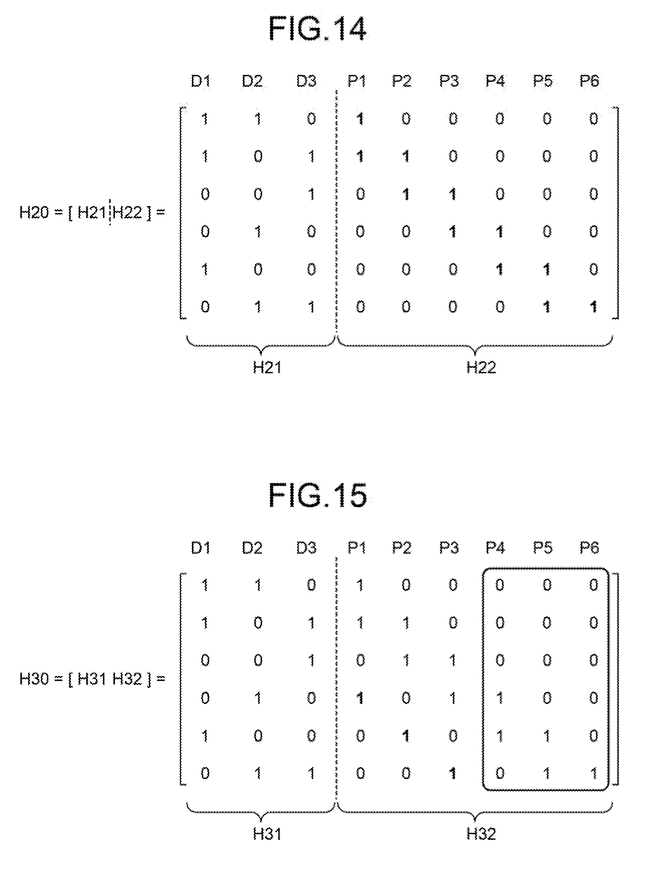

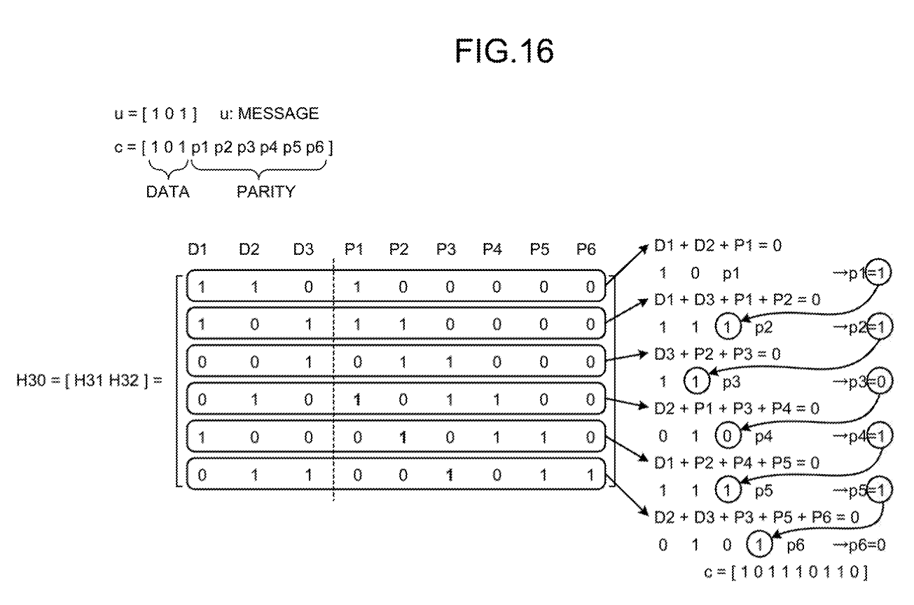

FIG. 11A is a schematic for explaining an example of BER-SNR characteristics of the error correction for spatially coupled RA coding (without circulation) without the use of the present invention. In the example illustrated in FIG. 11A, the error floor appears because the parity operation matrix H12 has some columns with a column weight of two or less. By contrast, FIG. 11B is a schematic for explaining an example of BER-SNR characteristics of the error correction for spatially coupled RA coding in the fourth embodiment (with circulation). In the example illustrated in FIG. 11B, the error floor is improved, because every column in the parity operation matrix H12 has a column weight of three or more.

In the coding unit 21 according to the fourth embodiment, the parity operation matrix H12 included in the parity check matrix H10 for spatially-coupled RA coding has a matrix along the diagonal, a circulant matrix positioned one row below the diagonal, and a circulant matrix at the fourth row below the diagonal, and the parity check matrix H10 in which each column has a column weight of three or more. As a result, the error floor can be improved.

The coding unit 21 according to the fourth embodiment calculates, based on the information operation matrix H11 and the parity operation matrix H12 included in the parity check matrix H10, and on the respective sets of initial values assigned to [p9, p10, p11, p12], the parity bit sequences corresponding to the respective sets of initial values. The coding unit 21 then compares the less-significant bit sequence of each of the parity bit sequences corresponding to the respective sets of initial values with the corresponding set of the initial values in the setting. The coding unit 21 then outputs the parity bit sequence with the less-significant bit sequence matching the corresponding set of initial values in the setting, concatenates the parity bit sequence to the message bit sequence, and outputs the code word c. As a result, even when used is the parity check matrix H10 for spatially-coupled RA coding, in which each column has a column weight of three or more, the parity bit sequence can be calculated.

Moreover, in the coding unit 21 according to the fourth embodiment, the accumulator units 34 corresponding to the respective sets of initial values are arranged in parallel to calculate the parity bit sequences corresponding to all of the respective patterns of [p9, p10, p11, p12], and compares the less-significant bit sequence of each of the parity bit sequences with the corresponding set of the initial values in the setting. The coding unit 21 then outputs the parity bit sequence with the less-significant bit sequence matching the corresponding set of initial values in the setting. As a result, the parity bit sequence can be calculated even when used is the parity check matrix H10 in which each column has a column weight of three or more.

In the fourth embodiment, by applying to spatially-coupled RA coding, a high error correction performance and a low error floor can be both achieved, without complicating the coding process excessively.

The first to the third embodiments described above are implemented using a matrix along the diagonal, a circulant matrix positioned one row below the diagonal, a circulant matrix positioned three rows below the diagonal in the parity operation matrix H2, but the embodiment is not limited to such a configuration, and the configuration may be changed as appropriate. The predetermined number of rows is not limited to the third or the fourth low below the diagonal, and may be changed as appropriate.

Explained for the coding unit 21 according to the fourth embodiment is a configuration in which the spatially-coupled RA coding are applied to the accumulator unit 34 according to the first embodiment, but spatially-coupled RA coding may be applied to the accumulator unit 34A according to the second embodiment or to the accumulator unit 34B according to the third embodiment, and may be changed as appropriate.

The coding unit 21 according to the embodiments described above is provided internal to the optical transport apparatus 1, but the embodiment is not limited to optical signals, and may also be used in coding electric signals.

Furthermore, the elements included in each of the units illustrated in the drawings do necessarily need to be configured physically in the way as illustrated in the drawing. In other words, the specific ways in which each of the apparatuses is distributed or integrated are not limited to those illustrated in the drawings, and such specific configurations may be, entirely or partly, functionally or physically distributed or integrated into any units depending on various loads and utilizations.

Furthermore, the processing functions executed by each of the apparatuses may be, entirely or partly, executed by a central processing unit (CPU) (or a micro-computer such as a macro-processing unit (MPU) or a micro-controller unit (MCU)). Furthermore, the processing functions may be, entirely or partly, executed by a computer program parsed and executed by a CPU (or a micro-computer such as an MPU or an MCU), or by a piece of hardware using a wired logic.

According to one aspect, the error floor can be improved.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A coding apparatus comprising:
a parity check matrix that includes a parity operation matrix including a matrix along a diagonal, a circulant matrix positioned one row below the diagonal, and a circulant matrix positioned a predetermined number of rows below the diagonal, and an information operation matrix;
a calculator that sets, in response to an input of a bit sequence of a message, every pattern of initial values to a less-significant bit sequence of parity bits corresponding to the number of the predetermined rows, the parity bits being used in calculating a parity bit sequence using an operational expression designated by the parity operation matrix and the information operation matrix, and that calculates parity bit sequences for the respective patterns of the initial values;
a selector that selects a parity bit sequence corresponding to one of the patterns of initial values when the less-significant bit sequence of the parity bit sequence corresponding to such a pattern of initial values matches the pattern of initial values; and
a synthesizer that concatenates the selected parity bit sequence to the bit sequence of the message, and that outputs a resultant code word.

2. The coding apparatus according to claim 1, wherein the calculator includes 2̂ (the predetermined number of rows) accumulators that calculate parity bit sequences for the respective patterns of the initial values, and the accumulators are arranged in parallel.

3. The coding apparatus according to claim 1, wherein the calculator includes:
a setter that sets the patterns of initial values; and
an accumulator that calculates the parity bit sequences for the respective patterns of initial values set by the setter.

4. The coding apparatus according to claim 1, wherein the calculator includes:
a setter that sets the patterns of initial values; and
a plurality of accumulators that calculate the parity bit sequences for the respective patterns of initial values set by the setting unit, the accumulators being arranged in parallel.

5. The coding apparatus according to claim 1, wherein the parity check matrix is a parity check matrix for weight-3 repeat accumulate coding.

6. The coding apparatus according to claim 1, wherein the parity check matrix is a parity check matrix for spatially coupled repeat accumulate coding.

7. A transport apparatus comprising a coding apparatus that outputs a code word in response to an input of a bit sequence of a message, the coding apparatus comprising:
a parity check matrix that includes a parity operation matrix including a matrix along a diagonal, a circulant matrix positioned one row below the diagonal, and a circulant matrix positioned a predetermined number of rows below the diagonal, and an information operation matrix;
a calculator that sets, in response to the input of the bit sequence of the message, every pattern of initial values to a less-significant bit sequence of parity bits corresponding to the number of the predetermined rows, the parity bits being used in calculating a parity bit sequence using an operational expression designated by the parity operation matrix and the information operation matrix, and that calculates parity bit sequences for the respective patterns of the initial values;
a selector that selects a parity bit sequence corresponding to one of the patterns of initial values when the less-significant bit sequence of the parity bit sequence corresponding to such a pattern of initial values matches the pattern of initial values; and
a synthesizer that concatenates the selected parity bit sequence to the bit sequence of the message, and that outputs a resultant code word.

8. A coding method comprising:
Providing, by a processor of a coding apparatus, a parity check matrix including a parity operation matrix including a matrix along a diagonal, a circulant matrix positioned one row below the diagonal, and a circulant matrix positioned a predetermined number of rows below the diagonal, and an information operation matrix;
setting, by the processor, in response to an input of a bit sequence of a message, every pattern of initial values to a less-significant bit sequence of parity bits corresponding to the number of the predetermined rows, the parity bits being used in calculating a parity bit sequence using an operational expression designated by the parity operation matrix and the information operation matrix, and calculating parity bit sequences for the respective patterns of the initial values;
selecting, by the processor, the parity bit sequence corresponding to one of the patterns of initial values when the less-significant bit sequence of the parity bit sequence corresponding to such a pattern of initial values matches the pattern of initial values; and
concatenating, by the processor, the selected parity bit sequence to the bit sequence of the message, and outputting a resultant code word.
